(19) United States
(12) Patent Application Publication
(10) Pub. No.: US 2021/0307180 A1
(43) Pub. Date: Sep. 30, 2021

(54) DISPLAY DEVICE AND ASSEMBLING METHOD FOR THE SAME

(71) Applicant: PEGATRON CORPORATION, Taipei City (TW)

(72) Inventor: Chih-Hao LU, TAIPEI CITY (TW)

(21) Appl. No.: 17/194,849

(22) Filed: Mar. 8, 2021

(30) Foreign Application Priority Data
Mar. 24, 2020 (TW) 109109821

(51) Int. Cl. H05K 5/00; H05K 5/03; G02F 1/1333

(52) U.S. Cl. CPC H05K 5/0017; G02F 1/133325; H05K 5/03

(57) ABSTRACT

The present invention relates to a display device and an assembling method for the same. The assembling method comprises the following steps. A display module is mounted on a cover, and is simultaneously positioned at a specific position on the cover to form a positioning baseline. Then, an outer frame is mounted on the cover, and loops around to form a display space to accommodate the display module. The outer frame has a surrounding part and an abutting part. The surrounding part surrounds and abuts the display module to be positioned on the cover. The abutting part abuts the display module toward the cover. The outer frame is directly formed with the surrounding part, which enables the outer frame to be positioned by the display module, so the assembling steps and the overall structure are simplified to reduce the manufacturing cost and the assembling time.

### CROSS-REFERENCE TO RELATED APPLICATION

Pursuant to 35 U.S.C. § 119(a), this application claims the benefit of the priority to Taiwan Patent Application No. 109109821, filed on Mar. 24, 2020. The content of the prior application is incorporated herein by its entirety.

### BACKGROUND

### 1. Technology Field

The present invention relates to a display device, particularly a laptop monitor or a tablet computer, and the assembling method thereof.

### 2. Description of the Related Art

As shown in FIG. 8, in the existing technology, a monitor of a laptop comprises a cover 91 (the aluminum shell of the rear cabinet), a positioning frame 92 (the plastic skeleton of the rear cabinet), a display module 93 (such as a Liquid Crystal Display Module, LCM) and an outer frame 94 (the front cabinet).

As shown in FIG. 9, during the assembly, the positioning frame 92 is mounted on the cover 91 first, and the position of the positioning frame 92 on the cover 91 is precisely controlled by a positioning fixture, so the positioning frame 92 can be used as a positioning baseline later.

Next, the display module 93 is mounted on the cover 91 and arranged in the accommodation space surrounded by the positioning frame 92. The positioning frame 92 surrounds and abuts the peripheral of the display module 93, so as to precisely control the position of the display module 93.

At last, the outer frame 94 is engaged with the positioning frame 92 by hooks, and assembled with the peripheral of the display module 93 by pressing, to prevent the display module 93 from dropping off easily. The assembly is approximately completed at this stage.

However, the existing technology has the following disadvantages.

First, the positioning frame 92 and the outer frame 94 are two separate parts; therefore two different molds are needed for their manufacture, and an additional assembling step for the two parts is necessary in the assembly, thereby resulting in a higher manufacture cost.

Second, structures such as hooks that hook each other are needed to be arranged on the positioning frame 92 and the outer frame 94, and the positioning frame 92 and the outer frame 94 are relatively wide, so it is hard to achieve a narrow outer frame for the monitor. However, the narrow outer frame is the fashion trend pursued by modern consumers.

Third, both the positioning frame 92 and the outer frame 94 have two elongated segments on two lateral sides of the monitor, and a long hook with a strong bound should be avoided on said two elongated segments because it is hard for disassembly and maintenance in the future. Alternatively, multiple hooks are arranged spaced apart on said two elongated segments, but the arrangement of the spaced hooks results in a wavy deformation of the outer frame 94, which is an appearance defect. Specifically, when the width of the outer frame 94 becomes as narrow as possible, which reduces the structural strength, the deformation problem has become a serious issue.

Therefore, both the structure and the assembling method of the display device in the existing technology need to be improved.

### SUMMARY

To overcome the shortcomings of the existing technology, the objective of the present invention is to provide a display device and the assembling method thereof, which can reduce the number of parts needed for the display device, and achieve a narrow outer frame without causing the wavy deformation problem and the like.

To achieve the above-mentioned objective, the technical solution of the present invention is to develop a display device assembling method, which comprises the following steps. First, a display module is mounted on a cover, in which the display module is positioned at a specific position on the cover while the display module is being mounted on the cover, and the display module is not positioned by abutting the cover against a peripheral of the display module. Then an outer frame is mounted on the cover which has been mounted with the display module, in which the outer frame loops around to form a display space to accommodate the display module. The outer frame has a surrounding part and an abutting part, both the surrounding part and the abutting part extend towards the display space. The surrounding part surrounds and abuts the peripheral of the display module to position the outer frame on the cover. The abutting part abuts a surface, which is opposite to the cover, of the display module.

To achieve the above-mentioned objective, the present invention further provides a display device comprising a cover, a display module, and an outer frame. The cover has an outer surface and an assembling surface opposite to each other. The display module is mounted on the assembling surface of the cover. A peripheral of the display module does not abut the cover in a direction perpendicular to a normal line of the display module. The outer frame is mounted on the assembling surface of the cover, and loops around the display module to form a display space to accommodate the display module. The outer frame has a surrounding part and an abutting part, both the surrounding part and the abutting part extend towards the display space; the surrounding part surrounds and abuts the peripheral of the display module to position the outer frame on the cover. The abutting part abuts a surface of the display module, opposite the cover.

The advantages of the present invention include: the surrounding part of the outer frame is formed by combining the conventional positioning frame into the outer frame, so the surrounding part still surrounds and abuts the peripheral of the display module, to strengthen and fix the display module, thereby reducing the molding cost in the manufacture because the number of parts is reduced by one. In addition, during the assembly, the display module is mounted on the cover first and works as a positioning baseline, so the outer frame can be positioned in accordance with the display module later, which means that one assembling step can be omitted without affecting the positioning effect. Therefore, the assembling time can be reduced in the present invention. At last, in the present invention, since the conventional positioning frame is directly formed on the outer frame, no hook needs to be disposed between the positioning frame and the outer frame, and the problems resulted from hooks, such as a wider outer frame or a wavy deformation of the outer frame, can be avoided. Hence, the present invention achieves the above objective.

### BRIEF DESCRIPTION OF THE DRAWINGS

FIG. 1 is a perspective view of the display device of the present invention.

FIG. 2 is an exploded view of the display device of the present invention.

FIG. 3 is a perspective view showing part of the outer frame of the display device of the present invention.

FIG. 4 is a sectional top view of the display device of the present invention.

FIG. 5 is a sectional front view of the display device of the present invention.

FIG. 6 is a flow chart of the display device assembling method of the present invention.

FIG. 7 is a schematic operational view of the display device assembling method of the present invention.

FIG. 8 is an exploded view of the conventional display device.

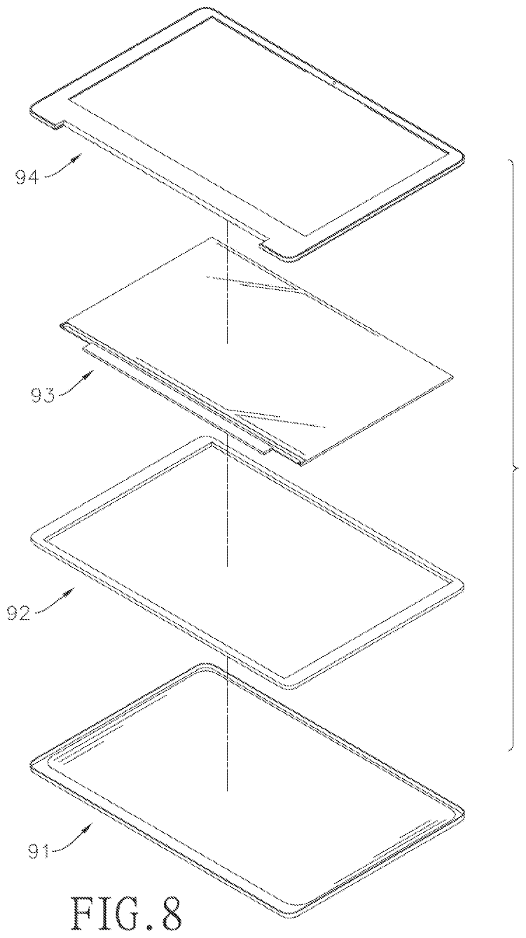

FIG. 9 is a schematic operational view of the assembling method of the conventional display device.

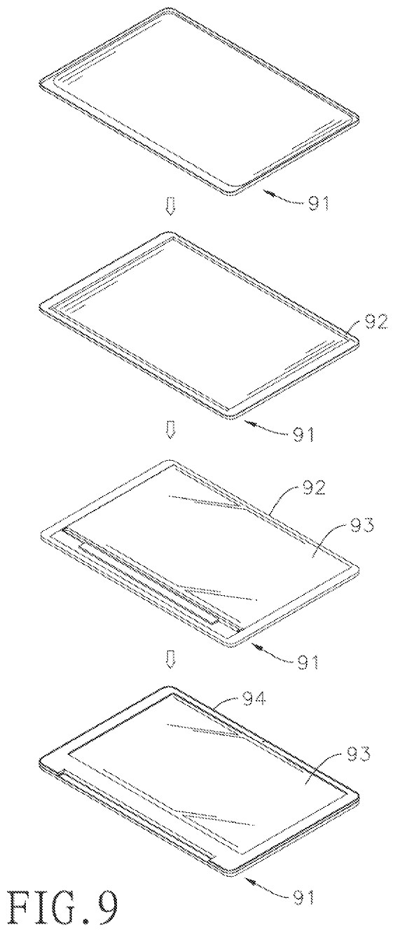

### DETAILED DESCRIPTION

To further illustrate the technical means and effects of the present invention for achieving the objective of the present invention, the following preferred embodiments will be made with reference to the accompanying drawings.

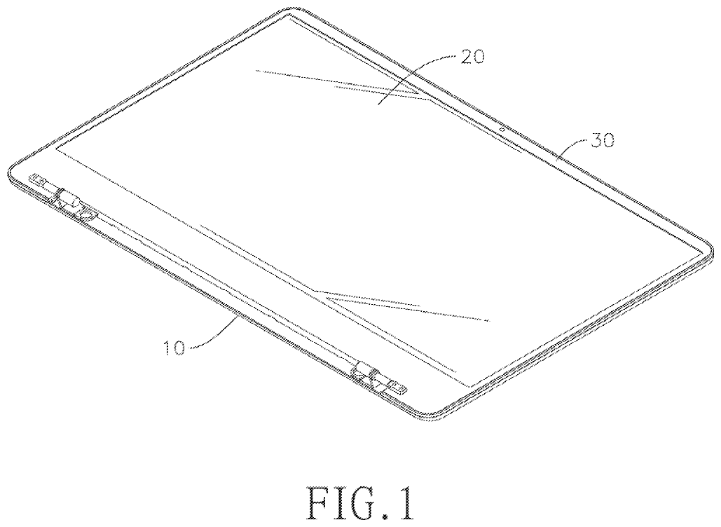

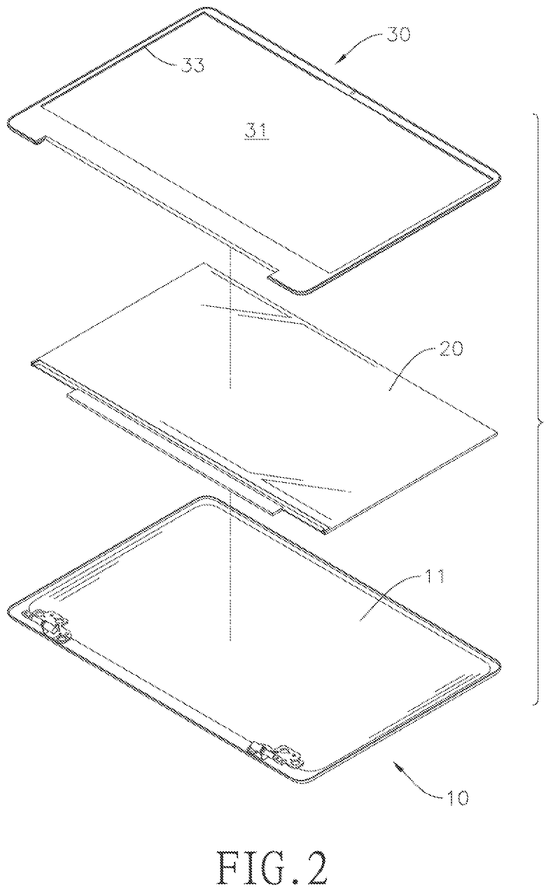

As shown in FIGS. 1 and 2, the display device of the present invention comprises a cover 10, a display module 20 and an outer frame 30. In a preferred embodiment, the display device of the present invention is a monitor of a laptop, but not limited thereto. The display device of the present invention may be a tablet computer or other display devices.

The cover 10 has an outer surface, and an assembling surface 11 opposite to the outer surface. The outer surface is the exterior surface, and the assembling surface 11 is the surface for arranging a variety of parts. In a preferred embodiment, the cover 10 is made of aluminum, but not limited thereto. Other materials commonly may be used for laptop or tablet computer, depending on the practical situations.

The display module 20 is disposed on the assembling surface 11 of the cover 10. In a preferred embodiment, the display module 20 is an LCD display module, but other display modules may be used. Additionally, in a preferred embodiment, glue is provided between the display module 20 and the cover 10. In other words, the display module 20 is adhered to the cover 10 with glue, but not limited thereto. Other mounting means may be applied.

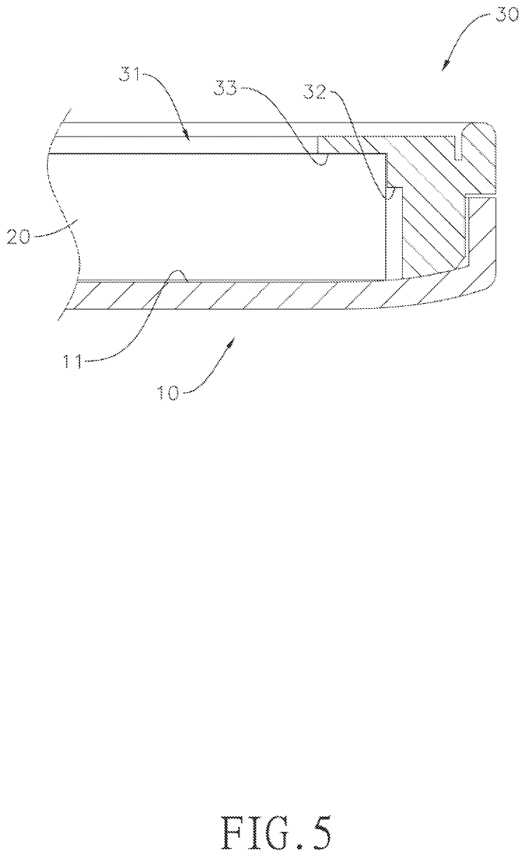

As shown in FIGS. 2 to 5, the outer frame 30 is disposed on the assembling surface 11 of the cover 10, and surrounds the display module 20. The outer frame 30 loops around to form a display space 31 to accommodate the display module 20. The display space 31 is where a user may see information displayed by the display module 20. In a preferred embodiment, glue is provided between the outer frame 30 and the cover 10. In other words, the outer frame 30 is adhered to the cover 10 with glue, but not limited thereto. Other mounting means may be applied.

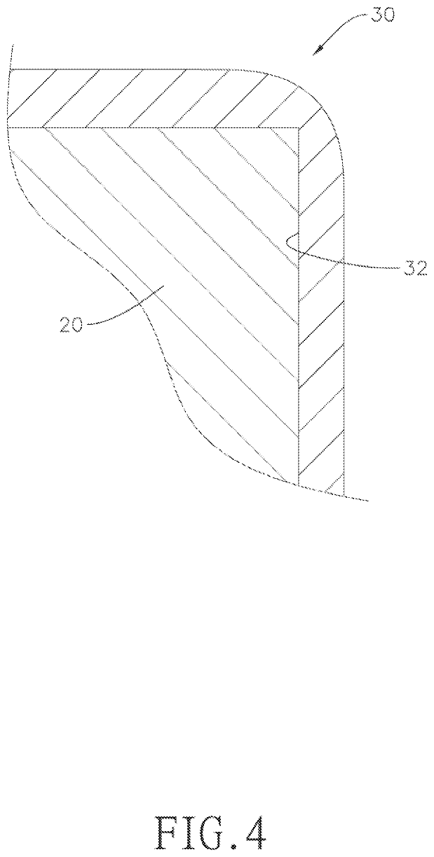

The outer frame 30 has a surrounding part 32 and an abutting part 33. The surrounding part 32 and the abutting part 33 both extend to the display space 31. The surrounding part 32 surrounds and abuts the peripheral of the display module 20 so the display module 20 can precisely position the outer frame 30 at a specific position on the cover 10. In a preferred embodiment, the surrounding part 32 is a complete loop (preferably rectangular loop) abutting the whole peripheral of the display module 20 (as shown in FIG. 4), but not limited thereto. The surrounding part 32 may have multiple segments which are arranged spaced apart and abut only parts of the peripheral of the display module 20.

The surface, which faces the cover 10, of the abutting part 33 abuts the surface, which is not mounted on the cover 10, of the display module 20 (i.e., the surface opposite “the surface of the display module 20 mounted on the cover 10”), to assist in fixing the display module 20 on the cover 10, and prevent the display module 20 from dropping off. In a preferred embodiment, the surrounding part 32 and the abutting part 33 connect to each other, but not limited thereto. The surrounding part 32 and the abutting part 33 may be arranged spaced apart.

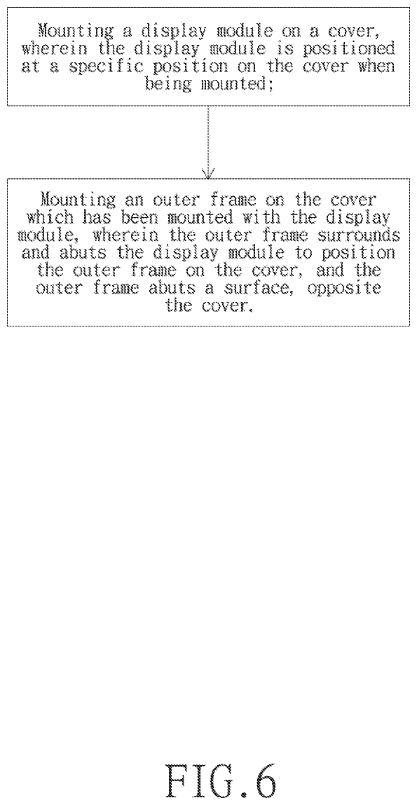

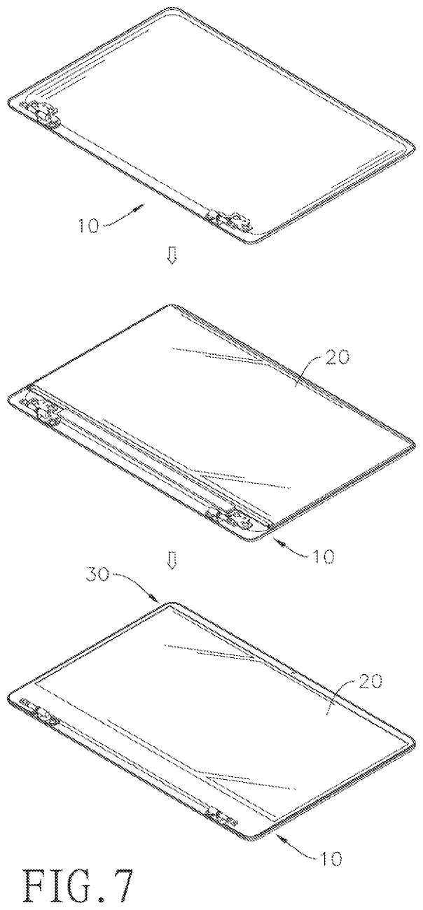

As shown in FIGS. 6 and 7, the display device assembling method of the present invention comprises the following steps.

Firstly, one surface of a display module 20 is mounted on a cover 10. The display module 20 is positioned at a specific position on the cover 10 while the display module 20 is being mounted on the cover 10. In a preferred embodiment, the display module 20 is positioned at the specific position on the cover 10 by a positioning fixture, but not limited thereto. Other positioning means may be used as long as the display module 20 can be precisely positioned at a specific position on the cover 10. In a preferred embodiment, the display module 20 is glued to the cover 10, but other mounting means may be used.

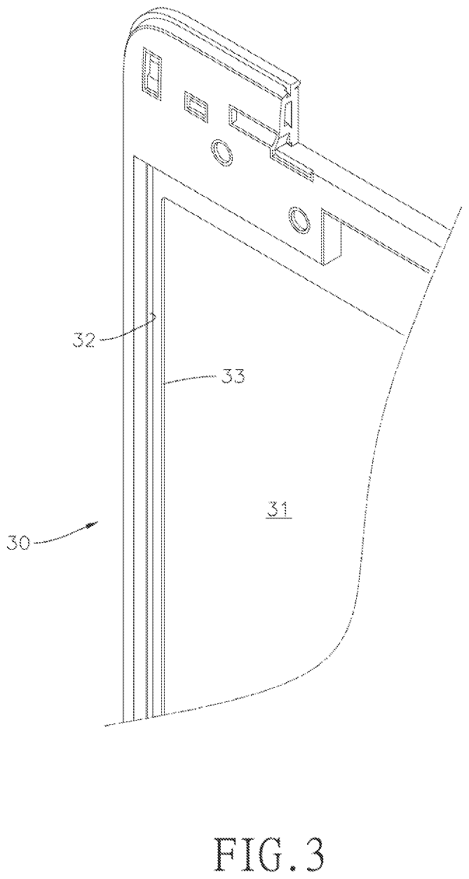

Afterwards, the outer frame 30 is mounted on the cover 10 which has been mounted with the display module 20. As shown in FIGS. 3 to 5, the outer frame 30 loops around to form a display space 31 to accommodate the display module 20. The outer frame 30 has a surrounding part 32 and an abutting part 33, and both the surrounding part 32 and the abutting part 33 extend towards the display space 31. The surrounding part 32 surrounds and abuts the peripheral of the display module 20 to position the outer frame 30 on the cover 10 Similarly, in a preferred embodiment, the surrounding part 32 is a complete loop abutting the whole peripheral of the display module 20, but not limited thereto. Since the peripheral of the pre-positioned display module 20 abuts the surrounding part 32 of the outer frame 30, the display module 20 works as a positioning baseline to position the outer frame 30 on the cover 10.

The surface, which faces the cover 10, of the abutting part 33 abuts the surface, which is not mounted on the cover 10, of the display module 20 (i.e., the surface opposite “the surface of the display module 20 mounted on the cover 10”), to assist in fixing the display module 20 on the cover 10.

In a preferred embodiment, the outer frame 30 is glued to the cover 10, but other mounting means may be applied.

In the present invention, the display module 20 is simultaneously mounted and positioned on the cover 10 first to form a positioning baseline, so the outer frame 30 can be directly positioned in accordance with the display module 20, thereby simplifying the assembling steps and reducing the assembling time. Further, the surrounding part 32, which can be directly positioned in accordance with the display module 20, is directly formed on the outer frame 30, so that the overall structure is simplified and the manufacturing cost is lowered. The objective of the present invention is achieved accordingly.

It should be understood that the descriptions proposed herein are just preferred examples for the purpose of illustrations only, not intended to limit the scope of the present invention in any way. Having described the invention in detail, it will be apparent to those skilled in the art that modifications, variations, and equivalent embodiments are possible without departing the scope of the invention defined in the appended claims. Furthermore, it should be understood that all simple modifications, variations, and equivalent embodiments substantively based on the present invention still fall within the scope of the present invention.

What is claimed is:

1. A display device assembling method comprising:
mounting a display module on a cover, wherein the display module is positioned at a specific position on the cover when being mounted; and
mounting an outer frame on the cover which has been mounted with the display module, the outer frame looping around to form a display space to accommodate the display module, wherein the outer frame has a surrounding part and an abutting part both extending towards the display space; the surrounding part surrounds and abuts a peripheral of the display module to position the outer frame on the cover; the abutting part abuts a surface, which is opposite to the cover, of the display module.

2. The display device assembling method as claimed in claim 1, wherein the step of mounting the display module on the cover comprises using a positioning fixture to position the display module at a specific position of the cover.

3. The display device assembling method as claimed in claim 1, wherein the step of mounting the display module on the cover comprises gluing the display module to the cover.

4. The display device assembling method as claimed in claim 2, wherein the step of mounting the display module on the cover comprises gluing the display module to the cover.

5. The display device assembling method as claimed in claim 1, wherein the step of mounting the outer frame on the cover comprises gluing the outer frame to the cover.

6. The display device assembling method as claimed in claim 2, wherein the step of mounting the outer frame on the cover comprises gluing the outer frame to the cover.

7. The display device assembling method as claimed in claim 3, wherein the step of mounting the outer frame on the cover comprises gluing the outer frame to the cover.

8. The display device assembling method as claimed in claim 4, wherein the step of mounting the outer frame on the cover comprises gluing the outer frame to the cover.

9. A display device comprising:
a cover having an outer surface and an assembling surface opposite to each other;
a display module mounted on the assembling surface of the cover; and
an outer frame mounted on the assembling surface of the cover and looping around to form a display space to accommodate the display module; the outer frame having a surrounding part and an abutting part both extending towards the display space; the surrounding part surrounding and abutting a peripheral of the display module to position the outer frame on the cover, and the abutting part abutting a surface of the display module, opposite the cover.

10. The display device as claimed in claim 9, wherein glue is provided between the display module and the cover, to adhere the display module to the cover.

11. The display device as claimed in claim 9, wherein glue is provided between the outer frame and the cover, to adhere the outer frame to the cover.

12. The display device as claimed in claim 10, wherein glue is provided between the outer frame and the cover, to adhere the outer frame to the cover.
